(19) United States
(12) Patent Application Publication
(10) Pub. No.: US 2012/0275026 A1
(43) Pub. Date: Nov. 1, 2012

(54) LOW REFLECTANCE FINGERPRINT RESISTANT SURFACE FOR DISPLAYS

(75) Inventors: Ying Zhou, Spring, TX (US); Neerja Saran, The Woodlands, TX (US); Martin A. Kykta, Austin, TX (US); Daniel K. Van Ostrand, Conroe, TX (US); Ed S. Ramakrishnan, Spring, TX (US); Robert J. Petcavich, The Woodlands, TX (US)

(73) Assignee: UNIPIXEL DISPLAYS, INC., The Woodlands, TX (US)

(21) Appl. No.: 13/097,494

(22) Filed: Apr. 29, 2011

(51) Int. Cl. G02B 1/11; B05D 1/36; C23C 16/44; B05D 5/06; B05D 3/02; B82Y 30/00

(52) U.S. Cl. 359/601; 427/164; 977/773

(57) ABSTRACT

Specular and diffuse reflection and fingerprints are reduced associated with a display are reduced through the use of any or all of an anti-reflection (AR) coating, a self-assembled monolayer (SAM) coating, and micro-structures to selectively deflect or diffract the incident light.

### BACKGROUND

Displays are used in a wide variety of applications. Displays that are touch sensitive in operation also are becoming increasingly more common. The use of touch screens as the preferred human interface of gaming devices, music playback devices, tablet computers, screen control panels in airplanes, and other devices is increasing. Depending on the incident angle of ambient light on a display screen (be it touch sensitive or non-touch sensitive) excessive glare may result that can make the information displayed on the screen difficult to see. Specular and diffuse reflection can be particularly problematic for certain displays and uses. For example, avionic displays may suffer from a low contrast ratio and strong glare because the plane's cockpit is often in an environment in which light from either the sun or the scattered light from the clouds impedes visibility. Further, the ease of viewability of information on a touch screen is often impaired by fingerprints from the user touching the screen. Even display screens that are not touch sensitive nevertheless may become marred by fingerprints of a user. Moreover, displays (both touch sensitive and non-touch sensitive) suffer from glare and fingerprint problems.

### SUMMARY

Various embodiments are disclosed herein to reduce the first surface (i.e., the surface of the display structure facing the user) specular reflection and diffuse reflection on a display screen from ambient light, while also achieving sufficient surface energy to avoid visible fingerprints and being easily cleaned. Embodiments of the invention include (1) the use of anti-reflection (AR) coatings, together with self-assembled monolayer (SAM) coatings or other surface treatments to manage the surface energy on microstructured optical surfaces; (2) the use of optical micro-structures to selectively deflect or diffract the incident light into directions that are not of interest, and (3) a combination of using diffracting optical micro-structures and anti-reflection coating together with a surface treatment that manages the surface energy.

For example, a display structure comprises a transparent substrate, an anti-reflection (AR) coating covering at least a portion of a surface of the substrate, and a self-assembled monolayer (SAM) provided on the AR coating.

Other embodiments are directed to method of fabrication a display structure. Such methods comprise depositing an AR coating on a transparent substrate; and providing a SAM on the AR coating.

Yet other embodiments are directed to a display structure that comprises a transparent substrate, a plurality of transparent microstructures provided on the substrate, and an AR coating over the microstructures.

Further still, some embodiments are directed to a display structure that comprises a transparent substrate and a plurality of transparent microstructures provided on the substrate all of which are oriented in a common direction on the substrate.

### BRIEF DESCRIPTION OF THE DRAWINGS

For a detailed description of exemplary embodiments of the invention, reference will now be made to the accompanying drawings in which:

FIG. 1 illustrates a substrate on which an anti-reflection (AR) coating is provided;

FIG. 2 illustrates a substrate on which an AR coating and self-assembled monolayer (SAM) are provided;

FIGS. 3-6 illustrate various method embodiments of forming a SAM layer on an AR coating;

FIG. 7 illustrates an embodiment in which microstructures are provided on a substrate;

FIG. 8 defines a coordinate system; and

FIGS. 9A-9C illustrate various substrates with different angles of microstructures relative an incident light source.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .”

The terms “touch screen” and “touch sensitive display” are synonymous, as are the terms “display,” “screen,” and “display screen.”

The term “display structure” refers to any type of structure that is part of, or adapted to be attached to, a display screen. The display structure may comprise an outer surface of the display screen itself, a cover plate that is adapted to be attached to a display screen, or an ad adhesive film adapted to be adhered to a display. The display structure includes the various features (e.g., AR coatings, SAM coatings, microstructures, etc.) described herein.

The terms “substrate” and “film” are synonymous.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

### Overview

Various embodiments are disclosed herein to reduce the first surface (i.e., the surface of the display structure facing the user) specular reflection and diffuse reflection on a display screen from ambient light, while also achieving sufficient surface energy to avoid visible fingerprints and being easily cleaned. By way of an overview, the embodiments include (1) the use of anti-reflection (AR) coatings, together with self-assembled monolayer (SAM) coatings or other surface treatments to manage the surface energy on microstructured optical surfaces; (2) the use of optical micro-structures to selectively deflect or diffract the incident light into directions that are not of interest, and (3) a combination of using diffracting optical micro-structures and anti-reflection coating together with a surface treatment that manages the surface energy.

The display structure described herein having any of the aforementioned features is part of, or attached to, a display screen. The display screen may comprise type of display such as a flat panel display (FPDs such as liquid crystal displays (LCDs)), an organic light emitting display (OLEDs), a micro-electro-mechanical system (MEMS) display, etc. The display screen may or may not be touch sensitive. The display structure may comprise a substrate such as an adhesive film, a cover plate, or outer surface of the display itself.

### AR Coatings

Some embodiments use an AR coating. In such embodiments, the AR coatings may comprise one or more AR layers. The AR coating may comprise a stack of inorganic dielectric coatings, organic solid coatings, nano-particle based coatings, etc. With the properly designed anti-reflection coating, specular reflection and diffuse reflection can be significantly reduced and thus substantially improve the contrast ratio and image quality of the display in high ambient light conditions, especially when the light originates from an off-normal direction.

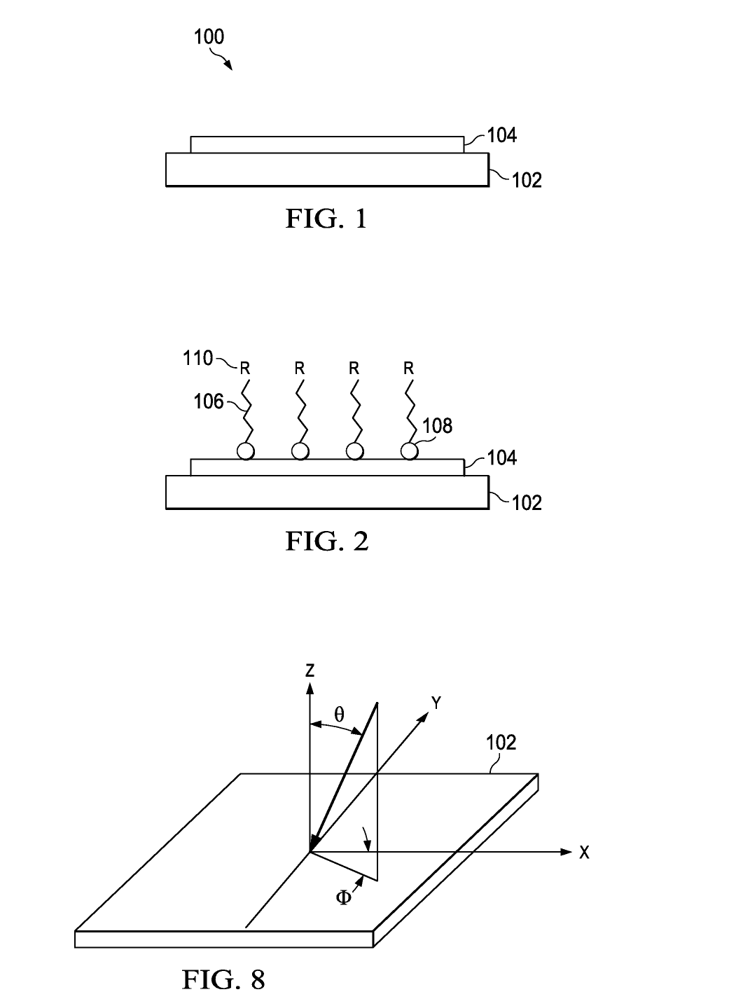

In accordance with various embodiments, one or more types of AR coatings are provided on the display structure to reduce the first surface specular reflection and diffuse reflection thereby increasing the contrast ratio and image quality of the display, especially under strong ambient light conditions. FIG. 1 illustrates a display structure 100 comprising a substrate 102 onto which an AR coating 104 has been applied. The substrate may comprise an adhesive film, a cover plate, or an outer surface of the display screen itself.

In the display arena, the specular reflection and diffuse reflection of the top surface (surface closest to the viewer) are often of the most interest because the surface reflection from the top surface plays a critical role in determining the contrast ratio especially under the strong ambient light conditions. It is not uncommon to see the outdoor contrast ratio from a transmissive LCD panel drop from about 200:1 to less than 10:1 under strong sunlight (e.g., at noon the surface luminance reflected from a Lambertian surface is 30,000 nits). As a result of such strong sunlight conditions, the displayed image would appear washed out. The surface reflection of a flat surface in air at normal angle is calculated as: R=(n−1)²/(n−1)², where n is the refractive index of the surface. For a glass substrate with refractive index of 1.5, the first surface specular reflection is about 4%.

### Inorganic AR Coatings

The AR coatings 104 applied to the substrate may comprise inorganic coatings. Inorganic dielectric AR coatings, also called thin-film coatings or interference coatings, comprise thin (typically sub-micron) layers of transparent dielectric materials that are deposited on the substrate. The function of such inorganic dielectric coatings is to modify the reflectivity and transmission properties of the surface through optical interference from multiple optical interfaces. Such inorganic dielectric coatings can be used, for example, on glass substrates, plastic substrates, and smooth polymer surfaces (optically polished). Inorganic dielectric coatings are deposited through vacuum evaporation, electron beam deposition, ion-assisted deposition (IAD), ionized beam sputtering (IBS), molecular beam epitaxy (MBE), chemical vapor deposition (CVD), etched, etc. Interference dielectric coatings are used for an optical surface to manage the reflectivity and transmission.

In some embodiments, a single AR layer is used, while in other embodiments, a stack of dielectric layers is used. In a dielectric stack, the stack preferably comprises alternating layers of high and low refractive indices. The resulting dielectric stack achieves desirable reflection and transmission within a certain bandwidth. Materials suitable for the dielectric stack include oxides such as SiO₂, TiO₂, Al₂O₃, and Ta₂O₅, and fluorides such as MgF₂, LaF₃, and AlF₃. For example, a four-layer AR coating stack can reduce specular reflection from 4.1% to 0.61%.

### Organic AR Coatings

In some embodiments, the AR coating 104 comprises a low refractive index (n-1.33-1.4) organic polymeric material from the fluoropolymer family such as fluorinated ethylene propylene, polytetrafluorothylene, tetrafluoroethylene, hexafluoropropylene vinylidnene fluoride, perfluoroalkoxy, and ethylene tetrafluoroethylene. These coatings preferably are about ¼ wavelength thick. Such organic AR coatings can be conveniently applied over large areas with strong adhesion and relatively low cost.

The polymers preferably are cured by, for example, application of heat or ultraviolet (UV) radiation to form semi-interpenetrating networks that traps the fluoropolymer component. Being soluble in specific organic solvents, in some embodiments solutions of the uncured blends are used to make coatings and to cast films, which are crosslinkable. These coatings are optically clear, robust and strongly adherent to reflective substrates including glass, polymer films, metals, crystal substrates and the like. Different polymer blends like amorphous fluoropolymers, or certain cross-linkable terpolymers derived from fluorine-containing acrylic monomers with non-fluorinated acrylic monomers are usable for anti reflection if their index of refraction is near the square root of the refractive index of the substrate. Based on amorphous fluoropolymer containing carbon and fluorine, and hydrogen and oxygen, they may show a refractive index as low as 1.33.

### Nano-Particles

Other embodiments comprise an anti-reflection film or film stack on substrates employing aqueous colloidal dispersions of metal oxide nanoparticles. As opposed to the deposition process required for inorganic dielectric coatings, the optical coatings based on aqueous nanoparticles can be put down on a substrate using cost-effective spin coat, dip coat, or spray coat techniques. Spin coating provides a way to uniformly deposit sub-100 nm films with metal oxide nanoparticle loading in aqueous colloidal solutions. And such films may comprise an anti-reflective stack on a plastic substrate. One or more after-coating processes such as baking, UV curing, or thermal curing are employed depending on different types of solution and resin used. For spin coating, for example, the thickness of the film can be controlled by the loading of the nanoparticles, the spin-off speed, and solution viscosity. The particles being used comprise, for example, silica, silicon dioxide, ceria, cerium dioxide, and other such materials. The mean particle diameter can be 10-20 nm range which is sufficiently small not to scatter light in the visible light region. Specifically, the index of refraction of the film can be tuned from 1.45 to 1.54 using silica nanoparticles and from 1.54 to 1.95 using ceria nanoparticles.

Teflon-based AR surface engineered coatings are thermally curable organosiloxane-based system with colloidal silica dispersed throughout its matrix. The addition of inorganic (mineral) colloidal silica to an organic (plastic) siloxan resin produces a coating that marries the physical and mechanical properties of the organic lens substrate to the inorganic AR stack, thereby bridging the chemistry gap between the relatively flexible lens substrate and the brittle anti-reflection stack.

A single layer of nanoparticle may reduce the specular reflection from the first surface from about 4% down to about 0.5% and a simple two layer anti-reflective stack may reduce the specular reflection from about 4% to about 0.3% for a target wavelength. Over the whole visible wavelength range, approximately 2% reflection is readily achievable and less than 1% reflection is achievable for multi layer coatings.

On a micro-structured surface (discussed below), this method gives a conformal coating for anti-reflection purpose, whose performance may be comparable to, or better than those of sol-gel based techniques.

### Surface Energy Management

In some embodiments, the surface energy of the film is altered by the addition of various coatings to achieve target fingerprint resistance, scratch resistance, hardness, and adhesion. These surface energy management coatings may be used, for example, if the anti-reflection coatings applied have lowered the surface energy out of the optimal range (generally water contact angle between 60-120°) for fingerprint resistance purposes. If antireflection coatings do not change surface energy significantly while still meeting the optical reflectance specifications, such as fluoropolymer conformal coatings, these surface energy control coatings may not be necessary. If surface energy management is indicated, for example, a self-assembled monolayer (SAM) coating can be applied.

### Self-Assembled Monolayer (SAM) Coatings

A SAM coating is an organized layer of amphiphilic molecules in which one end of the molecule, the “head group” shows a special affinity for a substrate. FIG. 2 illustrates a SAM 106. As shown, the head group 108 of the SAM 106 attaches to the AR coating 104. The SAM also comprises a tail with a functional group 110 at the terminal end.

SAMs are created by the chemisorption of hydrophilic “head groups” onto a substrate from either the vapor or liquid phase followed by a slow two-dimensional organization of hydrophobic “tail groups”. Initially, adsorbate molecules form either a disordered mass of molecules or form a “lying down phase”, and over a period of several hours, begin to form crystalline or semicrystalline structures on the substrate surface. The hydrophilic “head groups” assemble together on the substrate, while the hydrophobic tail groups assemble distally from the substrate. Areas of close-packed molecules nucleate and grow until the surface of the substrate is covered in a single monolayer. Adsorbate molecules adsorb readily because they lower the surface energy of the substrate and are stable due to the strong chemisorption of the “head groups.” These bonds create monolayers that are more stable than the physisorbed bonds of Langmuir-Blodgett films. The monolayer packs tightly due to van der Waals interactions, thereby reducing its own free energy.

Head groups 108 are connected to an alkyl chain in which the terminal end can be functionalized (i.e., adding —OH, —NH3, or —COOH, PHO(OH)₂ groups) to vary the wetting and interfacial properties. An appropriate substrate is chosen to react with the head group. Substrates can be planar surfaces, such as silicon and metals, or curved surfaces, such as nanoparticles.

Alkanethiols can be used to implement a SAM 106. Alkanethiols are molecules with an alkyl chain, (C—C)” chain, as the back bone, a tail group, and a S—H head group. They preferably are used on noble metal substrates like gold (Au) because of the strong affinity of sulfur for these metals. Alkanethiol-based SAMs are easy to pattern via lithography, a useful feature for applications in nanoelectromechanical systems (NEMS). Additionally, alkanethiol-based SAMs can withstand harsh chemical cleaning treatments.

Another type of SAM uses alkylsilane. Alkylsilane can be used on nonmetallic oxide surfaces such as n-octadecylsilane and octadecyltrihydroxysilane.

Other embodiments of SAM layers are based on a phosphonate. A phosphonate-based SAM that combines a reactive phosphonic acid reacts with the surface through strong and stable metal phosphorous bonds. The tails project away from the surface and are chosen for their chemical functionality (non-stick, pro-stick, etc.). Phosphonate-based SAMs (SAMPs) can coat metals, metal oxides, glass, ceramics, particles, semiconductors, and even some polymer surfaces by drawing on structurally tailored phosphonic acids. The SAMP is covalently bound to the substrate surface. This permanent chemical bond is highly stable under ambient conditions.

Organometallics (OM) also can be used to activate surface metals, metal oxides, glass, ceramics, particles, semiconductors, and polymer surfaces. The OM is covalently bound to the substrate surface. This permanent chemical bond is highly stable under ambient conditions, and serves as a chemical anchor for the attachment of other coatings.

Yet other embodiments using SAMs comprise transition metal complexes (TMC) based with reactive metallic centers that are reactive to many surfaces including plastics, and an organic complex.

The SAM coating can be conveniently applied by wiping on, spraying, ink-jet printing, through a felt-tip marker, dip coating, and using any of a variety of industrial coating processes. TMCs can coat metals, metal oxides, glass, ceramics, particles, semiconductors, and polymer surfaces. The TMCs are chemically bound to the substrate surface and can be designed to be a permanent or temporary coating.

SAMs can be applied by vapor phase through physical vapor deposition techniques such as evaporative deposition, electron beam physical vapor deposition, sputter deposition, cathodic arc deposition, pulsed laser deposition as well as by using liquid phase reaction by dip coating, solution cast methods spin-coating, slot-die coating followed by post curing steps by heat, radiation.

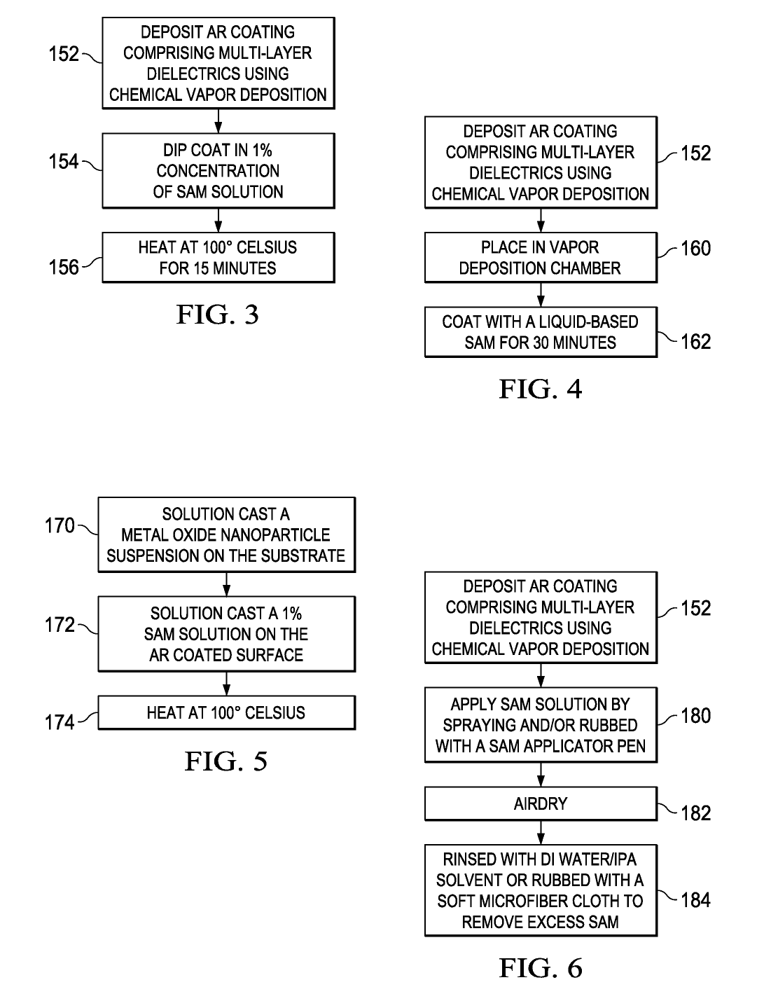

FIGS. 3-6 illustrate various methods of forming a display structure 100 by applying an AR coating and a SAM coating on a substrate. In FIG. 3, an AR coating comprising multi-layer dielectrics is deposited on the substrate using chemical vapor deposition (152). At 154, the substrate is then dip coated in a 1% concentration of a SAM solution, although the concentration can be varied as desired. At 156, the substrate is then heated/baked at, for example, 100 degrees centigrade for 15 minutes, although the temperature and baking time can be varied as desired.

In FIG. 4, the first step 152 is the same as in FIG. 3. That is, an AR coating comprising multi-layer dielectrics is formed using chemical vapor deposition. At 160, the substrate is placed in a vapor deposition chamber and at 162, the film is coated with a liquid-based SAM for 30 minutes, although the time can be varied as desired.

FIG. 5 shows a method embodiment in which metal oxide nanoparticles are solution cast on the substrate (170). At 172, the substrate is then solution cast in a 1% SAM solution and then heated at 100 degrees centigrade for a short period of time, for example, two minutes (174), although the SAM concentration, temperature and time can be varied as desired.

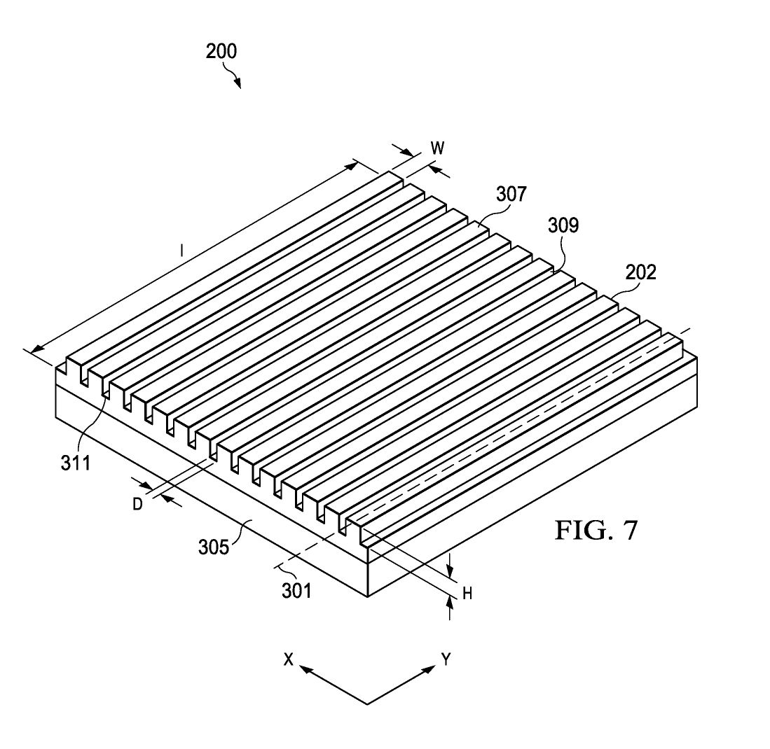

FIG. 6 shows a method in which the first step 152 is the same as described above with regard to FIGS. 3 and 4. At 180, the method comprises applying a SAM solution by spraying and/or rubbing with a SAM applicator pen. At 182, the substrate is allowed to air dry. At 184, substrate is then rinsed in de-ionized (DI) water/IPA solvent or rubbed with a soft microfiber cloth to remove any excess SAM.

### Plasma Surface Treatment

Rather than SAM coatings, plasma treatments for anti-stiction applications can also be used to alter the surface energy of the display structure 100. To meet any target surface energy requirements of ceramic-based AR coatings, certain C-Fx/H/SFx based chemistries can also be utilized. The surface modification is made either by surface frictionalization or polymerization by cross-linking. Anti-stiction coatings formed from fluorinated silane-based monomers can be applied to lower the surface energy in fingerprint resistant films. Anti-stiction coatings are self-assembled monolayer on the micro-structured surface (see below) of fingerprint resistant film, and are relatively thin when compared with the micro-structures and settles well into the valleys in between the structures and hence prevent attraction to external agents like dirt, particles.

### Substrates

As described above, a SAM coating 106 can be applied on top of an AR coating 104 which itself is applied to a substrate 102. The substrate can be any of a variety of surface such as glass, polymer substrates, mold inserts, etc. Suitable polymer substrates include acrylics, amorphous PET, PETG, polyurethanes, cellulose acetate, polyolefins, such as polyethylene, poly(isobutene), poly(isoprene), poly(4-methyl-1-pentene), polypropylene, ethylenepropylene copolymers, ethylene-propylene-hexadiene copolymers, and ethylene-vinyl acetate copolymers; styrene polymers, such as poly(styrene), poly(2-methylstyrene), styrene-acrylonitrile copolymers having less than about 20 mole-percent acrylonitrile, and styrene-2,2,3,3-tetrafluoropropyl methacrylate copolymers; halogenated hydrocarbon polymers, such as poly(chlorotrifluoroethylene), chlorotrifluoroethylene-tetrafluoroethylene copolymers, poly(hexafluoropropylene), poly(tetrafluoroethylene), tetrafluoroethylene-ethylene copolymers, poly(trifluoroethylene), poly(vinyl fluoride), and poly(vinylidene fluoride); vinyl polymers, such as poly(vinyl butyrate), poly(vinyl decanoate), poly(vinyl dodecanoate), poly(vinyl hexadecanoate), poly(vinyl hexanoate), poly(vinyl propionate), poly(vinyl octanoate), poly(heptafluoroisopropoxyethylene), poly(heptafluoroisopropoxypropylene), and poly(methacrylonitrile); acrylic polymers, such as poly(n-butyl acetate), poly(ethyl acrylate), poly(1-chlorodifluoromethyl)tetrafluoroethyl acrylate, polydi(chlorofluoromethyl)fluoromethylacrylate, poly(1,1-dihydroheptafluorobutyl acrylate), poly(1,1-dihydropentafluoroisopropyl acrylate), poly(1,1-dihydropentadecafluorooctyl acrylate), poly(heptafluoroisopropyl acrylate), poly 5-(heptafluoroisopropoxy)pentyl acrylate, poly 11-(heptafluoroisopropoxy)undecyl acrylate, polym2-(heptafluoropropoxy)ethyl acrylate, and poly(nonafluoroisobutyl acrylate); methacrylic polymers, such as poly(benzyl methacrylate), poly(n-butyl methacrylate), poly(isobutyl methacrylate), poly(t-butyl methacrylate), poly(t-butylaminoethyl methacrylate), poly(dodecyl methacrylate), poly(ethyl methacrylate), poly(2-ethylhexyl methacrylate), poly(n-hexyl methacrylate), poly(phenyl methacrylate), poly(n-propyl methacrylate), poly(octadecyl methacrylate), poly(1,1-dihydropentadecafluorooctyl methacrylate), poly(heptafluoroisopropyl methacrylate), poly(heptadecafluorooctyl methacrylate), poly(1-hydrotetrafluoroethyl methacrylate), poly(1,1-dihydrotetrafluoropropyl methacrylate), poly(1-hydrohexafluoroisopropyl methacrylate), and poly(t-nonafluorobutyl methacrylate); and polyesters, such a poly(ethylene terephthalate), poly(butylene terephthalate), and poly(ethylene terenaphthalate).

### Micro-Structured Surfaces

In accordance with some embodiments, the substrate comprises multiple “microstructures.” FIG. 7 shows one illustrative embodiment of a fingerprint resistant display structure 200 having elongated microstructures 202 with a generally square cross-sectional geometry (although the cross-sectional shape can be other than square). The microstructures 202 are provided on or are formed on a substrate 305 (e.g., a film) and extend along a majority of the length (in the direction identified by 301) of the substrate 305. Each microstructure 202 is defined by a pair of opposing, generally vertical side edges 309 and a top surface 307. Also, a channel 311 (or valley or recessed area) is provided or formed between adjacent microstructures 202. Fingerprint fluids migrate into the channels 311 thereby disrupting and “hiding” the fingerprint. As shown, most or all of the microstructures 202 are oriented in the same direction. The microstructures may be formed from any suitable material such as glass, polymeric materials (e.g., acrylates, urethanes, PET, etc.). In some embodiments, the microstructures are formed in a slightly curved hotdog shape and are raised above the carrier film surface.

The microstructures have almost vertical side walls to minimize image distortion. A general rule is that as the side wall area of the microstructures increases or the tilt angle of the sidewall changes from vertical, diffuse reflection increases and specular reflection decreases because the tilted side surface area tends to bend the light away from its specular reflection path. In addition, fewer defects in the microstructures result in higher specular reflection and smaller diffuse reflection because the defects are light scattering centers.

In order to have sufficient fingerprint resistance, the optical micro-structures 202 can have various geometries but the dimensions preferably are within a certain range. For example, the aspect ratio of the microstructures' height (h) to their width (w) is in the range of 0.2:1-4:1, and preferably 0.5:1-2:1. Microstructures with a low profile are beneficial in enhancing the shear strength of microstructures made of relatively low mechanical strength materials such as polymeric materials (e.g., acrylates, urethanes, PET, etc.). If needed, microstructures may be covered by a conformal hard coating to provide enhanced scratch resistance (e.g., 3H, 5H, etc.). The height (h) of each microstructure 202 is in the range of 3-10 um, and preferably 4-6 um. Further, the width (w) is typically 2-25 um, and preferably 3-10 um. The pitch (d) between each micro-structure is typically 5-60 um, and preferably 5-20 um. Optical microstructures whose dimensions are within the aforementioned ranges may provide excellent fingerprint resistance because skin oil and water quickly dissipate into the channels 311 and become invisible.

Because the display structure preferably is placed on the top surface of a display (e.g., a touch sensitive display), the display structure also should be transparent without introducing excessive optical artifacts such as Moiré, haze, color separation, etc. Each microstructure element has a flat upper surface 307 and flat side walls 309 that are vertical, or approximately vertical, to the display surface so as not distort the image. The display structure 200 preferably is placed in direct contact with the display top surface to eliminate an air gap which otherwise would cause double images and a parallax effect.

The microstructures 202 preferably have an “elongated” geometry that is defined as a microstructure having a length (l) dimension greater than its width (w) dimension. The microstructures 202 may comprise broken elongated structures placed end-to-end but typically the length (l) to width (w) ratio is at least 10:1. The resulting array of the microstructures 202 will have an axis along the length of the structures and have a fixed pitch in order to generate sufficient optical diffraction along the direction perpendicular to the axis.

In some embodiments, the microstructures 202 are all oriented in the same direction (e.g., as shown in FIG. 7) and have a fixed pitch. Other embodiments include a small amount of randomness for both the pitch and orientation. For example, the orientation and pitch may vary by less than 10% across the array of microstructures to help reduce any undesired Moiré effect while still preserving sufficient diffraction effect. Details of the microstructure shape and pattern can be varied according the reflectance requirement, display layout, and environment of the intended application.

FIG. 8 shows a coordinate system used to define the incident light and the orientation of the substrate/film 102. Under this system, azimuthal angle (φ) represents the orientation with respect to x axis within x-y plane while tilt angle (e) is the angle between an incident light beam and film normal, that is, the z axis. Without losing generality, one can always assume that light is incident from a direction defined by 0° azimuthal angle and a tilt angle e. The elongated diffracting micro-structures of the film can be oriented at a certain azimuthal angle φ.

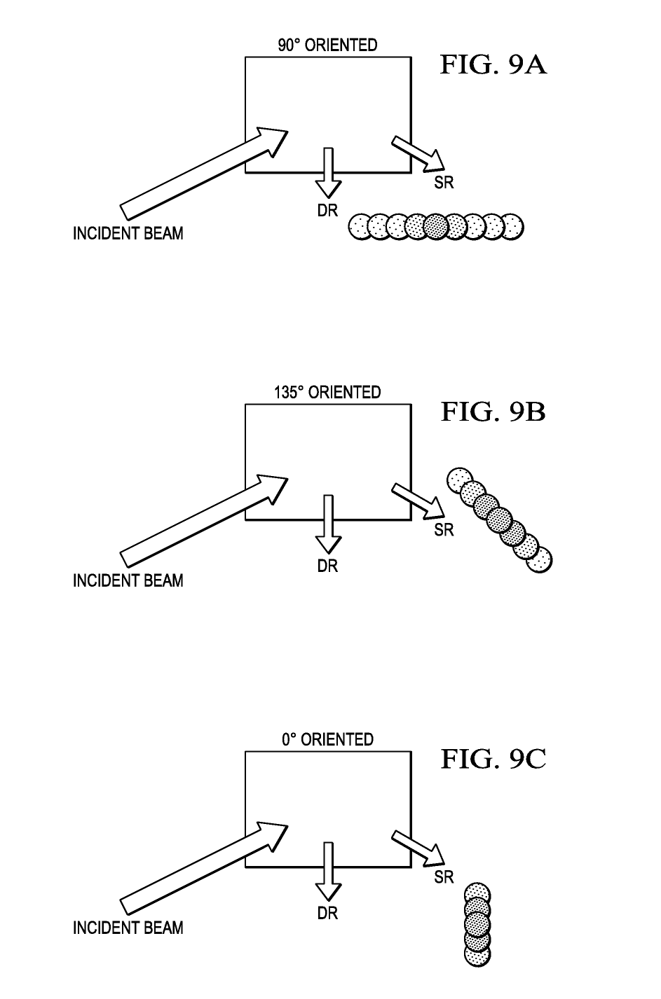

FIGS. 9A-9C show how incident light is diffracted into different directions based on different orientations of the elongated microstructures 202. Diffraction effect takes place when the reflected light off the top surface 307 of the microstructures and reflected light off the microstructure valleys 311 interfere with each other. As a result, a specular reflected beam is diffracted into multiple orders along the direction perpendicular to the channels. Diffraction is stronger when the incident light beam encounters periodic microstructures. Therefore, for a certain incident beam, i.e. incident beam from φ=180° azimuthal angle, diffraction is stronger for 90° orientated microstructures than 135° microstructures, and 0° being the weakest. If specular reflection and diffuse reflection are more of a concern along 0° rather than 90° azimuthal angle direction from which viewing direction mostly lies, φ can be chosen at approximately 45°.

Microstructures with AR and Surface Energy Management

In some embodiments, microstructures (such as structures 202) are provided and coated with an AR coating as described above. Further, the surface energy of the resulting AR-coated microstructures can be modified as explained above as well, for example, through application of a SAM layer.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A display structure, comprising:
a transparent substrate;
an anti-reflection (AR) coating covering at least a portion of a surface of the substrate; and
a self-assembled monolayer (SAM) provided on said AR coating.

2. The film of claim 1, wherein said AR coating comprises a dielectric coating.

3. The film of claim 1, wherein said AR coating comprises an inorganic dielectric coating.

4. The film of claim 1, wherein said AR coating comprises an organic dielectric coating.

5. The film of claim 1, wherein said AR coating comprises a fluoropolymer.

6. The film of claim 1, wherein said AR coating comprises multiple layers.

7. The film of claim 6, wherein at least one of said multiple layers comprises an oxide and another of said multiple layers comprises a fluoride.

8. The film of claim 1 wherein said AR coating comprises an aqueous colloidal dispersion of metal oxide nanoparticles

9. The film of claim 1 wherein said surface comprises microstructures.

10. A method of fabrication a display structure, comprising:
depositing an anti-reflection (AR) coating on a transparent substrate; and
providing a self-assembled monolayer (SAM) on said AR coating.

11. The method of claim 10 wherein depositing said AR coating comprises applying a chemical vapor deposition process.

12. The method of claim 10 wherein providing the SAM comprises dip-coating the film substrate with AR coating in a SAM solution followed by heating said film substrate.

13. The method of claim 10 wherein providing the SAM comprises placing said film substrate with AR coating in a vapor deposition chamber and coating said film substrate with AR coating with a liquid-based SAM solution.

14. The method of claim 10 wherein depositing said AR coating comprises casting a metal oxide nanoparticle suspension on said film substrate and then heating said film substrate, and wherein providing the SAM comprises casting a SAM solution on the AR coating followed by heating said substrate film.

15. A display structure, comprising:
a transparent substrate;
a plurality of transparent microstructures provided on said substrate; and
an anti-reflection (AR) coating over said microstructures;

16. The display structure of claim 15 further comprising a self-assembled monolayer (SAM) provided on said AR coating.

17. The display structure of claim 15, wherein said AR coating comprises a dielectric coating.

18. The display structure of claim 15, wherein said AR coating comprises an inorganic dielectric coating.

19. The display structure of claim 15, wherein said AR coating comprises an organic dielectric coating.

20. The display structure of claim 15, wherein said AR coating comprises a fluoropolymer.

21. The display structure of claim 15, wherein said AR coating comprises multiple layers.

22. The display structure of claim 21, wherein at least one of said multiple layers comprises an oxide and another of said multiple layers comprises a fluoride.

23. The display structure of claim 15 wherein said AR coating comprises an aqueous colloidal dispersion of metal oxide nanoparticles

24. A display structure, comprising:
a transparent substrate;
a plurality of transparent microstructures provided on said substrate all of which are oriented in a common direction on said substrate.
